(19) United States
(12) Patent Application Publication
(10) Pub. No.: US 2025/0236950 A1
(43) Pub. Date: Jul. 24, 2025

(54) SUBSTRATE PROCESSING SYSTEM

(71) Applicant: SAMSUNG ELECTRONICS CO., LTD., Suwon-si (KR)

(72) Inventor: Sangyub IE, Suwon-si (KR)

(73) Assignee: SAMSUNG ELECTRONICS CO., LTD., Suwon-si (KR)

(21) Appl. No.: 19/024,889

(22) Filed: Jan. 16, 2025

(30) Foreign Application Priority Data
Jan. 23, 2024 (KR) 10-2024-0010400
Apr. 30, 2024 (KR) 10-2024-0058123

(51) Int. Cl. C23C 16/44

(52) U.S. Cl. CPC C23C 16/4412

(57) ABSTRACT

A substrate processing system may include: a processing chamber in which process by-products are generated; a first line configured to provide a path through which the process by-products are discharged to outside the processing chamber; a first vacuum pressure sensor located on the first line and configured to measure a vacuum pressure value of the first line; a first valve located on the first line and configured to adjust a flow rate of a fluid passing through the first line; a second line connecting the first line to a first pump; a first analyzer configured to analyze parameters of the process by-products; a third line connecting the first line to the first analyzer; and a second vacuum pressure sensor located on the third line and configured to measure a vacuum pressure value of the third line.

### CROSS-REFERENCE TO RELATED APPLICATION

This application is based on and claims ranking under 35 U.S.C. § 119 to Korean Patent Application Nos. 10-2024-0010400, filed on Jan. 23, 2024, and 10-2024-0058123 filed on Apr. 30, 2024, in the Korean Intellectual Property office, the disclosures of which are incorporated by reference herein in their entireties.

### BACKGROUND

The disclosure relates to a substrate processing system, and more particularly, to a substrate processing system including a by-products analyzer.

An atomic layer deposition (ALD) process is a semiconductor manufacturing process. The ALD process is employed in a thin film deposition technology that uses a phenomenon wherein a single atom layer is adhered chemically to a layer. The ALD process may be used to deposit a thin film having a uniform nano-scale thickness in a complex three-dimensional structure.

An ALD apparatus may have a single-type structure or a batch-type structure. The ALD apparatus having the single-type structure may perform a process on one substrate. In the ALD apparatus having the single-type structure, gas may be supplied onto a substrate via a showerhead. The ALD apparatus with the batch-type structure may simultaneously perform a process on several substrates.

As the ALD process progresses, by-products are generated from a chamber, and mass spectrometry such as time-of-flight mass spectrometry (TOF-MS) is used to analyze the by-products.

### SUMMARY

The disclosure provides a substrate processing system with improved reliability.

In addition, the issues to be solved by the technical idea of the disclosure are not limited to those mentioned above, and other issues may be clearly understood by those of ordinary skill in the art from the following descriptions.

The disclosure provides a substrate processing system as described below.

According to one or more example embodiments, a substrate processing system may include: a processing chamber in which process by-products are generated; a first line configured to provide a path through which the process by-products are discharged to outside the processing chamber; a first vacuum pressure sensor located on the first line and configured to measure a vacuum pressure value of the first line; a first valve located on the first line and configured to adjust a flow rate of a fluid passing through the first line; a second line connecting the first line to a first pump; a first analyzer configured to analyze parameters of the process by-products; a third line connecting the first line to the first analyzer; a second vacuum pressure sensor located on the third line and configured to measure a vacuum pressure value of the third line; a second valve located on the third line and configured to adjust a flow rate of a fluid passing through the third line; and a first controller configured to control the first valve based on a signal received from the first vacuum pressure sensor and control the second valve based on a signal received from the second vacuum pressure sensor.

According to one or more example embodiments, a substrate processing system may include: a processing chamber in which process by-products are generated; a first line configured to provide a path through which the process by-products are discharged to outside the processing chamber; a first vacuum pressure sensor located on the first line and configured to measure a vacuum pressure value of the first line; a first valve located on the first line and configured to adjust a flow rate of a fluid passing through the first line; a second line connecting the first line to a first pump; an analyzer configured to analyze parameters of the process by-products; a third line connecting the first line to the analyzer; a second vacuum pressure sensor located on the third line and configured to measure a vacuum pressure value of the third line; a second valve located on the third line and configured to adjust a flow rate of a fluid passing through the third line; a first controller configured to control the first valve based on a signal received from the first vacuum pressure sensor; and a second controller configured to receive parameter analysis values from the analyzer of the process by-products; control the second valve based on a signal received from the second vacuum pressure sensor; and transmit the parameter analysis values to the first controller.

According to one or more example embodiments, a substrate processing system may include: a processing chamber in which process by-products are generated; a first line configured to provide a path through which the process by-products are discharged to outside the processing chamber; a first vacuum pressure sensor located on the first line and configured to measure a vacuum pressure value of the first line; a first valve located on the first line and configured to adjust a flow rate of a fluid passing through the first line; a second line connecting the first line to a first pump; an analyzer configured to analyze parameters of the process by-products; a third line connecting the first line to the analyzer; a second vacuum pressure sensor located on the third line and configured to measure a vacuum pressure value of the third line; a second valve located on the third line and configured to adjust a flow rate of a fluid passing through the third line, the second valve being arranged near the first line; a third valve located on the third line, and configured to adjust the flow rate of the fluid passing through the third line, the third valve being arranged near the analyzer; a fourth line connecting the analyzer to a second pump; a third vacuum pressure sensor located on the fourth line and configured to adjust a flow rate of a fluid passing through the fourth line; a fourth valve located on the fourth line and configured to adjust the flow rate of the fluid passing through the fourth line; a first controller configured to control the first valve based on a signal received from the first vacuum pressure sensor; and a second controller configured to receive parameter analysis values from the analyzer of the process by-products; control the second valve and the third valve based on the signal received from the second vacuum pressure sensor; control the fourth valve based on the signal received from the third vacuum pressure sensor; and transmit the parameter analysis values to the first controller.

According to one or more example embodiments, a substrate processing system may include: a processing chamber configured to process a substrate and generate process by-products; an analyzer configured to analyze parameters of the process by-products; a line configured to provide a path through which the process by-products are discharged to outside the processing chamber, the line connecting the processing chamber to the analyzer; a vacuum pressure sensor located on the line and configured to measure a vacuum pressure value of the line; a valve located on the line and configured to adjust a flow rate of the process by-products passing through the line; at least one processor; and memory storing instructions that when executed by the at least one processor, cause the at least one processor to control the valve based on a signal received from the vacuum pressure sensor.

### BRIEF DESCRIPTION OF THE DRAWINGS

Embodiments will be more clearly understood from the following detailed description taken in conjunction with the accompanying drawings in which:

FIG. 1 is a block diagram of a substrate processing system according to one or more embodiments;

FIG. 2A is a schematic cross-sectional view of one or more embodiments of a chamber in FIG. 1;

FIG. 2B is a schematic cross-sectional view of a chamber according to one or more embodiments;

FIG. 3 is a block diagram of a substrate processing system according to one or more embodiments;

FIG. 4A is a block diagram of a substrate processing system according to one or more embodiments;

FIG. 4B is a block diagram of a substrate processing system according to one or more embodiments;

FIG. 5 is a block diagram of a substrate processing center system according to one or more embodiments;

FIG. 6 is a block diagram of a substrate processing center system according to one or more embodiments;

FIG. 7A is a schematic diagram of an operation of the substrate processing system of FIG. 1;

FIG. 7B is a schematic diagram of an operation of the substrate processing system of FIG. 1; and

FIG. 7C is a schematic diagram of an operation of the substrate processing system of FIG. 1.

### DETAILED DESCRIPTION

Hereinafter, embodiments of the disclosure are described in detail with reference to the accompanying drawings. Identical reference numerals are used for the same constituent elements in the drawings, and duplicate descriptions thereof are omitted.

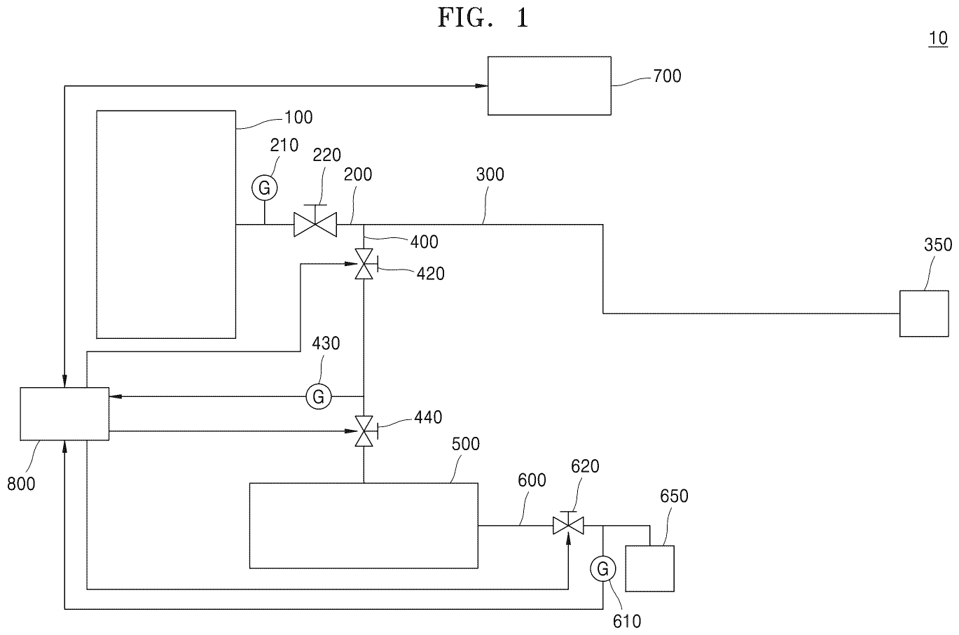

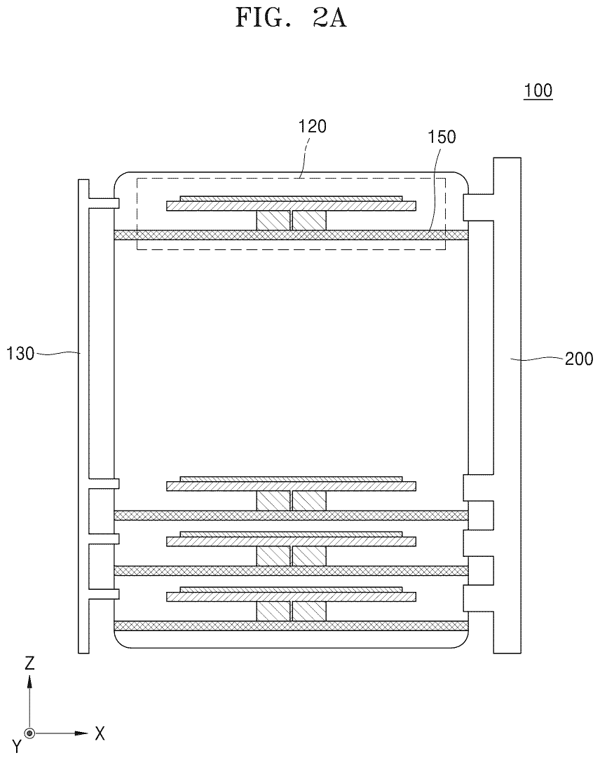

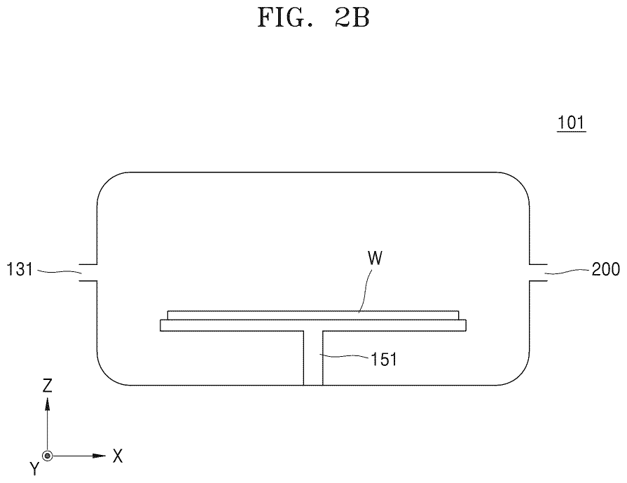

FIG. 1 is a block diagram of a first substrate processing system 10 according to one or more embodiments. FIG. 2A is a schematic cross-sectional view of one or more embodiments of a chamber 100 in FIG. 1. FIG. 2B is a schematic cross-sectional view of a chamber 101 according to one or more embodiments.

Referring to FIGS. 1 through 2B, a first substrate processing system 10 may include a processing chamber 100, a first line 200, a second line 300, a third line 400, a fourth line 600, a first analyzer 500, a first controller 700, and a second controller 800.

The processing chamber 100 may include a chamber in which a process related to a substrate W is performed, and the processing chamber 100 may serve as a housing having a space for processing the substrate W therein. The processing chamber 100 may have a kind of isolated space. As the processing chamber 100 is isolated from the outside, conditions for a process of treating the substrate W may be adjusted. For example, a temperature, a pressure, or the like inside the processing chamber 100 may be adjusted differently from the temperature, pressure, or the like outside the processing chamber 100, respectively.

According to one or more embodiments, the processing chamber 100 may include a chamber in which a deposition process is performed. For example, the processing chamber 100 may include a chamber in which a chemical vapor deposition (CVD) process is performed or a chamber in which an atomic layer deposition (ALD) process is performed. However, the process performed in the processing chamber 100 is not limited thereto. According to some embodiments, by-products may be generated during a process performed in the processing chamber 100. The by-products may include general by-products generated during a treatment process on the substrate W, and the by-products are not limited to a certain type.

The processing chamber 100 may be of various types. In some embodiments, the processing chamber 100 may be of a batch type, as illustrated in FIG. 2A. For example, a plurality of substrates W may be arranged in the processing chamber 100, and a deposition process may be performed on each of the plurality of substrates W.

In the drawings, a direction perpendicular to a surface of the substrate W may be understood as a Z-axis direction, and an X-axis direction and a Y-axis direction may be understood as directions in parallel with the surface of the substrate W. The X-axis direction and the Y-axis direction may be perpendicular to each other. The Z-axis direction may indicate a direction perpendicular to an X-Y plane. In addition, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

According to some embodiments, the processing chamber 100 may include a process module (processor) 120, a gas line 130, and a plate 150. The process module 120 may be defined as a space in which each substrate W is treated. The plate 150 on which the substrate W is arranged may be provided in the process module 120. According to some embodiments, a plurality of process modules (processors) 120 may be provided as being stacked in a vertical direction Z in the processing chamber 100. According to some embodiments, the two adjacent process modules 120 may be separated from each other by the plate 150 extending in a horizontal direction (X and Y). Accordingly, materials present in a process space of any one process module 120 may not move to the processing space of the other process module 120. The gas line 130 may be configured to provide a gas required for a process into the process module 120. The gas line 130 may supply a gas provided by a gas supply source to each of the plurality of process modules 120. As the process proceeds, by-products generated in the processing chamber 100 may be moved to the outside of the processing chamber 100 through the first line 200. The first line 200 may be connected to each of the plurality of process modules 120. The first line 200 may be connected to a first pump 350. The plurality of process modules 120 may be converted into a vacuum state through the first line 200.

According to some embodiments, a processing chamber 101 of the first substrate processing system 10 may be of a single type as illustrated in FIG. 2B. In other words, one substrate W may be arranged in the processing chamber 101, and a deposition process may be performed on the one substrate W.

According to some embodiments, the processing chamber 101 may include a substrate support apparatus 151 which supports the substrate W. According to some embodiments, the substrate support apparatus 151 may be configured to rotate about the center axis thereof in the vertical direction Z. A gas line 131 may be connected to one side surface of the processing chamber 101. The gas line 131 may provide a gas provided from a gas supply source into the processing chamber 101. As the process proceeds, by-products generated in the processing chamber 101 may be moved to the outside of the processing chamber 101 through the first line 200.

The first line 200 may be connected to the processing chamber 100. The first line 200 may provide a path through which the by-products generated in the processing chamber 100 is moved. A first vacuum pressure sensor 210 and a first valve 220 may be provided on the first line 200.

The first vacuum pressure sensor 210 may be configured to measure the pressure of the first line 200. For example, the first vacuum pressure sensor 210 may be configured to measure the vacuum pressure of the first line 200. According to some embodiments, the first vacuum pressure sensor 210 may include a McLeod gauge, a thermocouple gauge, a Pirani gauge, a convection gauge, an ionization gauge, a hot ionization gauge), a Penning gauge, etc.

In some embodiments, the first vacuum pressure sensor 210 may measure the vacuum pressure of the first line 200 and then transmit a signal to the first controller 700 based on the measured vacuum pressure value. According to some embodiments, the first vacuum pressure sensor 210 may be configured to transmit the vacuum pressure of the first line 200 to the first controller 700 in real time, or to transmit an abnormal signal to the first controller 700 when the vacuum pressure value of the first line 200 is greater than or less than a threshold value. However, the type of a signal received from the first vacuum pressure sensor 210 to the first controller 700 is not limited thereto.

In some embodiments, the first vacuum pressure sensor 210 may measure the vacuum pressure of the first line 200 and then transmit a signal to the second controller 800 based on the measured vacuum pressure value.

The first valve 220 may be configured to adjust the flow rate of the fluid moving along the first line 200. According to some embodiments, the first valve 220 may include a stop valve, a gate valve, a check valve, a plug valve, a ball valve, a butterfly valve, and a diaphragm valve. In some embodiments, the first valve 220 may adjust only the opening and closing of the first line 200. For example, the first valve 220 may adjust the opening and closing of the first line 200 so that the fluid may or may not pass through the first line 200. In some embodiments, the first valve 220 may adjust the opening and closing, and the flow rate of the fluid of the first line 200.

The first valve 220 may include an automatic valve. According to some embodiments, the first valve 220 may include an electric automatic valve, a pneumatic automatic valve, a hydraulic automatic valve, and a solenoid automatic valve.

The second line 300 and the third line 400 may include lines branched from the first line 200. The second line 300 may be configured to connect the first line 200 to the first pump 350. The second line 300 may provide a path through which the fluid having passed through the first line 200 moves to the first pump 350. The fluid passing through the first line 200 may be moved along the second line 300 by the first pump 350. The third line 400 may be configured to connect the first line 200 to the first analyzer 500. The third line 400 may provide a path through which the fluid having passed through the first line 200 moves to the first analyzer 500.

A second valve 420, a third valve 440, and a second vacuum pressure sensor 430 may be provided on the third line 400. The second valve 420 may be arranged close to the first line 200. The second valve 420 may be configured to adjust a flow rate of the fluid moving along the third line 400. For example, the second valve 420 may adjust the opening and closing of the third line 400 so that either the fluid passes through the third line 400 or the fluid does not pass through the third line 400. The second valve 420 may include a stop valve, a gate valve, a check valve, a plug valve, a ball valve, a butterfly valve, and a diaphragm valve. The second valve 420 may include an automatic valve. For example, the second valve 420 may include an electric automatic valve, a pneumatic automatic valve, a hydraulic automatic valve, and a solenoid automatic valve.

The second vacuum pressure sensor 430 may be configured to measure the pressure of the third line 400. For example, the second vacuum pressure sensor 430 may be configured to measure the vacuum pressure of the third line 400. According to some embodiments, the second vacuum pressure sensor 430 may include a McLeod gauge, a thermocouple gauge, a Pirani gauge, a convection gauge, an ionization gauge, a hot ionization gauge), a Penning gauge, etc.

In some embodiments, the second vacuum pressure sensor 430 may measure the vacuum pressure of the third line 400 and then transmit a signal to the first controller 700 based on the measured vacuum pressure value. According to some embodiments, the second vacuum pressure sensor 430 may transmit the vacuum pressure of the third line 400 to the first controller 700 in real time, or transmit an abnormal signal to the first controller 700 when the vacuum pressure value of the third line 400 is greater than or equal to, or less than or equal to a certain value. However, the type of a signal received from the second vacuum pressure sensor 430 to the first controller 700 is not limited thereto.

In some embodiments, the second vacuum pressure sensor 430 may measure the vacuum pressure of the third line 400 and then transmit a signal to the second controller 800 based on the measured vacuum pressure value. According to some embodiments, the second vacuum pressure sensor 430 may transmit the vacuum pressure of the third line 400 to the second controller 800 in real time, or transmit an abnormal signal to the second controller 800 when the vacuum pressure value of the third line 400 is greater than or equal to, or less than or equal to a certain value. However, the type of a signal received from the second vacuum pressure sensor 430 to the second controller 800 is not limited thereto.

The third valve 440 may be located near the first analyzer 500. The third valve 440 may be configured to adjust a flow rate of the fluid moving along the third line 400. The third valve 440 may include a stop valve, a gate valve, a check valve, a plug valve, a ball valve, a butterfly valve, a needle valve, and a diaphragm valve. The third valve 440 may include an automatic valve. According to some embodiments, the third valve 440 may include an electric motor automatic valve, a pneumatic automatic valve, a hydraulic automatic valve, and a solenoid automatic valve.

In some embodiments, the third valve 440 may adjust only the flow rate of the fluid passing through the third line 400. For example, the third valve 440 may adjust the degree of flow rate of the fluid passing through the third line 400, but may not control the opening and closing of the third line 400. In this case, the third valve 440 may include a needle valve. In addition, in some embodiments, the third valve 440 may adjust the opening and closing of the third line 400 and the entire flow rate of the fluid.

The first analyzer 500 may be configured to analyze by-products introduced through the third line 400. The first analyzer 500 may be configured to analyze parameters of the by-products. For example, the first analyzer 500 may be configured to measure the mass of the by-products. The first analyzer 500 may include a mass spectrometer. According to some embodiments, the first analyzer 500 may include a TOF MS, an optical emission spectroscopy (OES), a residual gas analyzer (RGA), etc. However, the first analyzer 500 is not limited to the TOF MS, the OES, and the RGA, and an analyzer capable of measuring parameters of by-products may be sufficient.

In the disclosure, the TOF MS, the OES, and the RGA may include conventionally known analyzers without particular limitation. The TOF MS may include a device which is capable of analyzing the mass of ionized ions by using the time of flight, and may include an ion source, a time of flight analyzer, a detector, and a signal amplifier. The TOF MS may ionize the by-products and measure the mass of the by-products based on the time that is taken for the ionized by-products to reach the detector in a vacuum tube. The TOF MS may include the Malditof MS, a quadrupole (Q)-TOF MS, or a linear trap quadrupole (LTQ)-orbitrap MS, but is not limited thereto.

The OES may be configured to measure the mass of the by-products by using an optical emission spectroscopy method. The OES may include any one of a monochrometer sensor, a charge coupled device (CCD)-OES sensor, and a scanning capacitance microscopy (SCM)-OES sensor. The monochrometer sensor may selectively pass and amplify only light of a particular wavelength among light received through a view port, generate an electrical signal corresponding to the particular wavelength, and measure the mass of the by-products. The CCD-OES may include a diffraction grating which decomposes plasma light generated in a chamber into a plurality of light signals having different wavelengths, a CCD which receives a plurality of different broken light signals from each other and converts them into a plurality of electrical signals, and a signal computation device which converts the plurality of electrical signals into data and perform computation. The SCM-OES sensor may include a sensor installed in a plasma processing apparatus for detecting a process value related to a plasma process, and may include various different sensors, such as a sensor sensing chemical compositions inside the plasma processing apparatus, a sensor sending power, and a sensor sensing pressure.

The RGA may include an ionizer, a mass analyzer, and an ion detector. The RGA may analyze neutrons outside a beam line, and output spectrum representing relative strength of various kinds inside a gas. Ions generate by the gas may be differentiated from masses by using an analyzer of the RGA.

The first analyzer 500 may be configured to transmit data obtained by analyzing the by-products to the second controller 800. For example, the first analyzer 500 may transmit the mass of the by-products to the second controller 800. However, the data received from the first analyzer 500 to the second controller 800 is not limited thereto.

When the analysis of the by-products introduced into the first analyzer 500 is completed, the by-products may be discharged to the outside of the first analyzer 500 via the fourth line 600. The first analyzer 500 may be connected to a second pump 650 through the fourth line 600. A fourth valve 620 and a third vacuum pressure sensor 610 may be provided von the fourth line 600.

The fourth valve 620 may be configured to adjust a flow rate of the fluid moving along the fourth line 600. For example, the fourth valve 620 may adjust the opening and closing of the fourth line 600 so that either the fluid passes through the fourth line 600 or the fluid does not pass through the third line 400. The fourth valve 620 may include a stop valve, a gate valve, a check valve, a plug valve, a ball valve, a butterfly valve, and a diaphragm valve.

The third vacuum pressure sensor 610 may be configured to measure the pressure of the fourth line 600. For example, the third vacuum pressure sensor 610 may be configured to measure the vacuum pressure of the fourth line 600. According to some embodiments, the third vacuum pressure sensor 610 may include a McLeod gauge, a thermocouple gauge, a Pirani gauge, a convection gauge, an ionization gauge, a hot ionization gauge, a Penning gauge, etc.

In some embodiments, the third vacuum pressure sensor 610 may measure the vacuum pressure of the fourth line 600 and then transmit a signal to the first controller 700 based on the measured vacuum pressure value. According to some embodiments, the third vacuum pressure sensor 610 may transmit the vacuum pressure of the fourth line 600 to the first controller 700 in real time, or transmit an abnormal signal to the first controller 700 when the vacuum pressure of the fourth line 600 is greater than or equal to, or less than or equal to a certain value. However, the type of a signal received from the third vacuum pressure sensor 610 to the first controller 700 is not limited thereto.

In some embodiments, the third vacuum pressure sensor 610 may measure the vacuum pressure of the fourth line 600 and then transmit a signal to the second controller 800 based on the measured vacuum pressure. For example, the third vacuum pressure sensor 610 may transmit the vacuum pressure of the fourth line 600 to the second controller 800 in real time, or transmit an abnormal signal to the second controller 800 when the vacuum pressure of the fourth line 600 is greater than or equal to, or less than or equal to a certain value. However, the type of a signal received from the third vacuum pressure sensor 610 to the second controller 800 is not limited thereto.

The first controller 700 may be configured to adjust an internal environment of the processing chamber 100. For example, the first controller 700 may adjust the amount of gas flowing into the processing chamber 100, adjust the temperature inside the processing chamber 100, or adjust the pressure inside the processing chamber 100. However, the environmental parameters inside the processing chamber 100 controlled by the first controller 700 are not limited thereto.

In some embodiments, the first controller 700 may be configured to adjust the first valve 220. The first controller 700 may adjust the opening and closing of the first valve 220 in response to the signal received from the first vacuum pressure sensor 210. When an abnormal signal is received from the first vacuum pressure sensor 210, the first controller 700 may close the first valve 220 to control the fluid no longer to pass through the first line 200. For example, when a change above a threshold occurs in the pressure inside the first line 200, the first controller 700 may control the first valve 220 to be closed in response to a signal received from the first vacuum pressure sensor 210. In addition, when the pressure inside the first line 200 returns to a normal value, the first controller 700 may control the first valve 220 to be at an open state again in response to a signal received from the first vacuum pressure sensor 210. In some embodiments, the first valve 220 may be controlled by the second controller 800. This issue is described below.

The first controller 700 may be implemented as hardware, firmware, software, or a combination thereof. For example, the first controller 700 may include a computing device, such as a workstation computer, a desktop computer, a laptop computer, and a tablet computer. The first controller 700 may also include a simple controller, at least one processor, a microprocessor, a complex processor, such as a CPU, and a GPU, a processor including software, dedicated hardware, or firmware. The first controller 700 may be implemented by, for example, application particular hardware, such as a DSP, a FPGA, and an ASIC. The first controller 700 may be implemented as instructions stored on a machine-readable medium that may be read and executed by one or more processors. In this case, the machine-readable medium may include an arbitrary mechanism for storing and/or transferring information in a form readable by a machine (for example, a computing device). For example, the machine-readable medium may include read-only memory (ROM), random access memory (RAM), a magnetic disk storage medium, an optical storage medium, a flash memory device, electrical, optical, acoustical, or other different forms of radio signals (for example, a carrier wave, infrared signals, digital signals, or the like), and other arbitrary signals.

The second controller 800 may be configured to control each of the second valve 420, the third valve 440, and the fourth valve 620. According to some embodiments, the second controller 800 may independently control each of the second valve 420, the third valve 440, and the fourth valve 620. The second controller 800 may control the second valve 420 and the third valve 440 in response to the signal received from the second vacuum pressure sensor 430. For example, when the pressure of the third line 400 is greater than or equal to, or less than or equal to a threshold, the second controller 800 may close the second valve 420 to prevent the fluid from passing through the third line 400. In addition, when the pressure of the third line 400 is greater than or equal to a threshold, the second controller 800 may close the third valve 440, or reduce the amount of fluid passing through the third line 400. In addition, in some embodiments, the second controller 800 may control the second valve 420 and the third valve 440 in response to a signal received from the third vacuum pressure sensor 610. For example, when the pressure of the third line 400 is greater than or equal to, or less than or equal to a threshold, the second controller 800 may adjust the second valve 420 and the third valve 440 to prevent the fluid from passing through the third line 400.

According to some embodiments, the second controller 800 may adjust the opening and closing of the fourth valve 620 in response to a signal received from the third vacuum pressure sensor 610. For example, when the pressure of the fourth line 600 is greater than or equal to, or less than or equal to a threshold, the second controller 800 may close the fourth valve 620 to prevent the fluid from passing through the fourth line 600. In addition, when the pressure of the fourth line 600 is recognized as a normal value, the second controller 800 may open the fourth valve 620 to control the fluid to pass through the fourth line 600.

According to some embodiments, the second controller 800 may be configured to transmit the data received from the analyzer to the first controller 700. For example, the second controller 800 may receive data on the mass of the by-products from the analyzer, and then transmit the data to the first controller 700. In this case, the first controller 700 may adjust the environment in the processing chamber 100 in response to the data received from the second controller 800.

In the first substrate processing system 10 according to the technical idea of the disclosure, the by-products generated in the processing chamber 100 may be moved to the first analyzer 500 through the third line 400 branched from the first line 200, and the by-products may be monitored by the first analyzer 500. In this case, because the first substrate processing system 10 according to the technical idea of the disclosure includes the second valve 420, the third valve 440, and the fourth valve 620 controlled by the second controller 800, the movement of the by-products may be automated. In addition, the second controller 800 may control the second valve 420, the third valve 440, and the fourth valve 620 in response to the pressure signal received via the first vacuum pressure sensor 210, the second vacuum pressure sensor 430, and the third vacuum pressure sensor 610. Accordingly, when an abnormality occurs in the pressure values of the first line 200, the second line 300, the third line 400, and the fourth line 600, the first substrate processing system 10 may protect the processing chamber 100 and the first analyzer 500 by limiting the movement of the fluid. For example, the first substrate processing system 10 may prevent the fluid flowing through the first line 200 and the second line 300 from flowing backward toward the processing chamber 100 due to an abnormality in the first pump 350, and may prevent the fluid flowing through the first line 200, the third line 400, and the fourth line 600 from flowing backward to the processing chamber 100 or the first analyzer 500 due to an abnormality in the second pump 650. In addition, the first substrate processing system 10 may prevent a high-pressure fluid from flowing toward the first analyzer 500 due to an abnormality in the processing chamber 100, and may prevent the high-pressure fluid from flowing toward the processing chamber 100. In this case, the abnormality occurring in the processing chamber 100 may be understood as a pressure haunting phenomenon, a vacuum leak phenomenon, etc.

In addition, because the first substrate processing system 10 receives pressure signals of the first line 200, the third line 400, and the fourth line 600 via a separate second controller 800, and in response to these, may control the second valve 420, the third valve 440, and the fourth valve 620, it may not be necessary to change the first controller 700 embedded in an existing first substrate processing system 10, and furthermore, because the effect described above may be obtained as only the second controller 800 is additionally added, a system may be established efficiently without changing a separate controller embedded or without developing a new controller to fit each apparatus when other type of apparatus is applied.

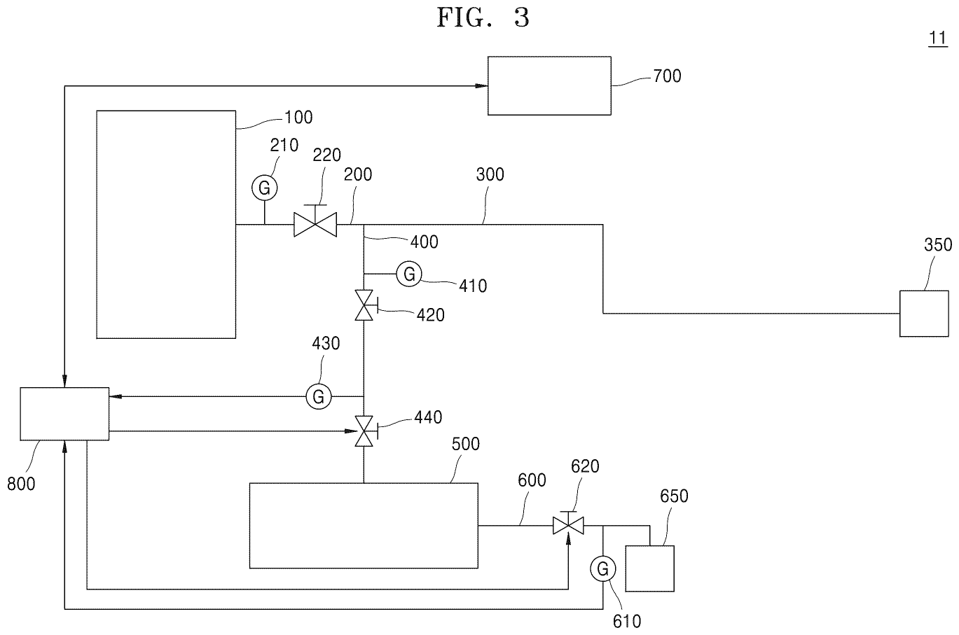

FIG. 3 is a block diagram of a substrate processing system 11 according to one or more embodiments. Hereinafter, duplicate descriptions of the first substrate processing system 10 given with reference to FIGS. 1 through 2B and the substrate processing system 11 to be given with reference to FIG. 3 are omitted, and differences therebetween are mainly described.

Referring to FIGS. 1 through 3, the substrate processing system 11 may include the processing chamber 100, the first line 200, the second line 300, the third line 400, the fourth line 600, the first analyzer 500, the first controller 700, and the second controller 800. The processing chamber 100 may include any one of an arrangement type and a single type. The first line 200 may be connected to the processing chamber 100. The first line 200 may provide a path through which the by-products generated in the processing chamber 100 is moved. A first vacuum pressure sensor 210 and a first valve 220 may be provided on the first line 200. The second line 300 and the third line 400 may include lines branched from the first line 200. The second line 300 may be configured to connect the first line 200 to the first pump 350. The third line 400 may be configured to connect the first line 200 to the first analyzer 500.

The second valve 420, the third valve 440, the second vacuum pressure sensor 430, and a fourth vacuum pressure sensor 410 may be provided on the third line 400. According to some embodiments, the second vacuum pressure sensor 430 may be located near the first analyzer 500, and the fourth vacuum pressure sensor 410 may be located near the first line 200. The fourth vacuum pressure sensor 410 may be configured to measure the pressure value of the third line 400. The fourth vacuum pressure sensor 410 may be configured to measure the vacuum pressure of the third line 400. According to some embodiments, the fourth vacuum pressure sensor 410 may include a McLeod gauge, a thermocouple gauge, a Pirani gauge, a convection gauge, an ionization gauge, a hot ionization gauge, a Penning gauge, etc.

The fourth vacuum pressure sensor 410 may measure the vacuum pressure of the third line 400, and then transmit a signal to the second controller 800 based on the vacuum pressure value. According to some embodiments, the fourth vacuum pressure sensor 410 may be configured to transmit the vacuum pressure of the third line 400 to the second controller 800 in real time, or to transmit an abnormal signal to the second controller 800 when the vacuum pressure of the third line 400 is greater than or less than a threshold value.

The second controller 800 may control the second valve 420 and the third valve 440 by using the vacuum pressure value of the third line 400 received from the second vacuum pressure sensor 430 and the fourth vacuum pressure sensor 410. Accordingly, the second controller 800 may detect the pressure abnormality of the third line 400 to adjust the second valve 420 and the third valve 440. In addition, because the fourth vacuum pressure sensor 410 is located at the beginning of the third line 400, the second controller 800 may detect whether an abnormality has occurred in the first line 200 and the third line 400 by comparing pressure values of the first line 200 and the third line 400, in response to the pressure signal received from the first vacuum pressure sensor 210 measuring the pressure value of the first line 200 and the pressure signal received from the fourth vacuum pressure sensor 410.

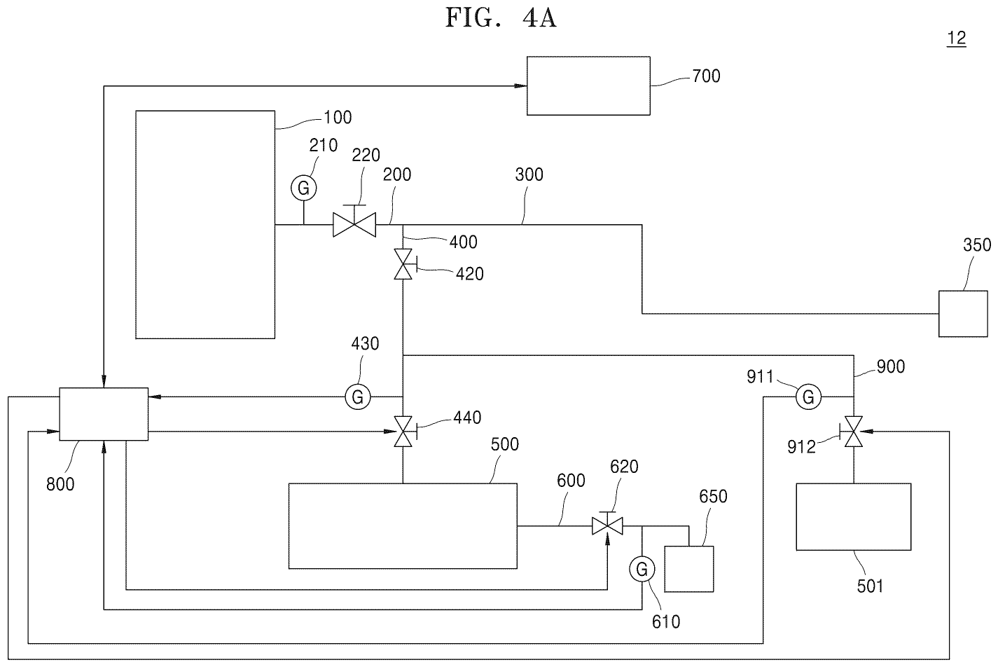

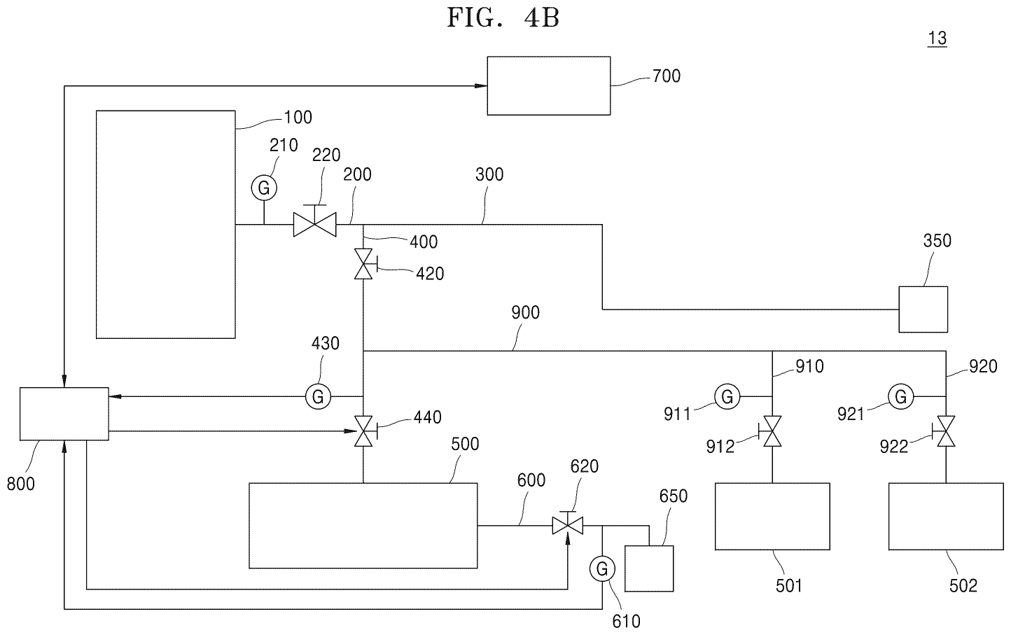

FIGS. 4A and 4B are block diagrams of substrate processing systems 12 and 13, respectively, according to embodiments. Hereinafter, duplicate descriptions of the first substrate processing system 10 given with reference to FIGS. 1 through 2B, and the substrate processing systems 12 and 13, respectively, to be given with reference to FIGS. 4A and 4B are omitted, and differences therebetween are mainly described.

Firstly, referring to FIG. 4A, the substrate processing system 12 may include the processing chamber 100, the first line 200, the second line 300, the third line 400, the fourth line 600, a fifth line 900, the first analyzer 500, the first controller 700, and a second analyzer 501. The processing chamber 100 may include any one of an arrangement type and a single type. The first line 200 may be connected to the processing chamber 100. The first line 200 may provide a path through which the by-products generated in the processing chamber 100 is moved. The first vacuum pressure sensor 210 and the first valve 220 may be provided on the first line 200. The second line 300 and the third line 400 may include lines branched from the first line 200. The second line 300 may be configured to connect the first line 200 to the first pump 350. The third line 400 may be configured to connect the first line 200 to the first analyzer 500. The second valve 420, the third valve 440, and a second vacuum pressure sensor 430 may be provided on the third line 400. The fifth line 900 may include a line branched from the third line 400. A fifth vacuum pressure sensor 911 and a fifth valve 912 may be provided on the fifth line 900. The fifth vacuum pressure sensor 911 may be configured to measure a pressure value of the fifth line 900. The fifth vacuum pressure sensor 911 may be configured to measure a vacuum pressure value of the fifth line 900. According to some embodiments, the fifth vacuum pressure sensor 911 may include a McLeod gauge, a thermocouple gauge, a Pirani gauge, a convection gauge, an ionization gauge, a hot ionization gauge, a Penning gauge, etc. The fifth vacuum pressure sensor 911 may measure the vacuum pressure of the fifth line 900, and then transmit a signal to the second controller 800 based on the vacuum pressure value. According to some embodiments, the fifth vacuum pressure sensor 911 may be configured to transmit the vacuum pressure of the fifth line 900 to the second controller 800 in real time, or to transmit an abnormal signal to the second controller 800 when the vacuum pressure of the fifth line 900 is greater than or less than a threshold value.

The fifth valve 912 may be configured to adjust a flow rate of the fluid moving through the fifth line 900. According to some embodiments, the fifth valve 912 may include a stop valve, a gate valve, a check valve, a plug valve, a ball valve, a butterfly valve, and a diaphragm valve. In some embodiments, the fifth valve 912 may adjust only the opening and closing of the fifth line 900. In some embodiments, the fifth valve 912 may control the opening and closing of the fifth line 900 and the entire flow rate of the fluid. The fifth valve 912 may include an automatic valve. According to some embodiments, the fifth valve 912 may include an electric motor automatic valve, a pneumatic automatic valve, a hydraulic automatic valve, and a solenoid automatic valve.

The second analyzer 501 may be configured to analyze by-products introduced through the fifth line 900. The second analyzer 501 may be configured to analyze parameters of the by-products. For example, the second analyzer 501 may be configured to measure the mass of the by-products. The second analyzer 501 may include a different type of analyzer from the first analyzer 500. In some embodiments, the second analyzer 501 may include an inexpensive analyzer compared to the first analyzer 500.

The second controller 800 may receive parameter analysis values of the by-products from each of the first analyzer 500 and the second analyzer 501. The second controller 800 may compare the parameter analysis values of the by-products received from each of the first analyzer 500 and the second analyzer 501. Accordingly, the substrate processing system 12 may accurately analyze the parameter values of the by-products.

In addition, the second controller 800 may adjust the fifth valve 912 based on the pressure value of the fifth line 900 transmitted by the fifth vacuum pressure sensor 911. For example, when the pressure of the fifth line 900 is greater than or less than a threshold, the second controller 800 may close the fifth valve 912 to prevent the fluid from passing through the fifth line 900. In this manner, the substrate processing system 13 may protect the first analyzer 500, the second analyzer 501, and the processing chamber 100.

Referring to FIG. 4B, the substrate processing system 13 may include the processing chamber 100, the first line 200, the second line 300, the third line 400, the fourth line 600, the fifth line 900, a sixth line 910, a seventh line 920, the first analyzer 500, the first controller 700, the second controller 800, the second analyzer 501, and a third analyzer 502. The processing chamber 100 may include any one of an arrangement type and a single type. The first line 200 may be connected to the processing chamber 100. The first line 200 may provide a path through which the by-products generated in the processing chamber 100 is moved. The first vacuum pressure sensor 210 and the first valve 220 may be provided on the first line 200. The second line 300 and the third line 400 may include lines branched from the first line 200. The second line 300 may be configured to connect the first line 200 to the first pump 350. The third line 400 may be configured to connect the first line 200 to the first analyzer 500. The second valve 420, the third valve 440, and the second vacuum pressure sensor 430 may be provided on the third line 400. The fifth line 900 may include a line branched from the third line 400. Each of the sixth line 910 and the seventh line 920 may include a line branched from the fifth line 900. The sixth line 910 may be configured to connect the fifth line 900 to the second analyzer 501. The seventh line 920 may be configured to connect the fifth line 900 to the third analyzer 502.

The fifth vacuum pressure sensor 911 and the fifth valve 912 may be provided on the sixth line 910. The fifth vacuum pressure sensor 911 may be configured to measure a pressure value of the sixth line 910. The fifth vacuum pressure sensor 911 may be configured to measure a vacuum pressure value of the sixth line 910. The fifth vacuum pressure sensor 911 may measure the vacuum pressure of the sixth line 910, and then transmit a signal to the second controller 800 based on the vacuum pressure value. According to some embodiments, the fifth vacuum pressure sensor 911 may be configured to transmit the vacuum pressure of the sixth line 910 to the second controller 800 in real time, or to transmit an abnormal signal to the second controller 800 when the vacuum pressure of the sixth line 910 is greater than or less than a threshold value.

The fifth valve 912 may be configured to adjust a flow rate of the fluid moving through the sixth line 910. In some embodiments, the fifth valve 912 may adjust only the opening and closing of the sixth line 910. In some embodiments, the fifth valve 912 may control the opening and closing of the sixth line 910 and the entire flow rate of the fluid. The fifth valve 912 may include an automatic valve.

The second analyzer 501 may be configured to analyze by-products introduced through the sixth line 910. The second analyzer 501 may be configured to analyze parameters of the by-products. For example, the second analyzer 501 may be configured to measure the mass of the by-products. The second analyzer 501 may include a different type of analyzer from the first analyzer 500. In some embodiments, the second analyzer 501 may include an inexpensive analyzer compared to the first analyzer 500.

A sixth vacuum pressure sensor 921 and a sixth valve 922 may be provided on the seventh line 920. The sixth vacuum pressure sensor 921 may be configured to measure a pressure value of the seventh line 920. The sixth vacuum pressure sensor 921 may be configured to measure a vacuum pressure value of the seventh line 920. According to some embodiments, the sixth vacuum pressure sensor 921 may include a McLeod gauge, a thermocouple gauge, a Pirani gauge, a convection gauge, an ionization gauge, a hot ionization gauge, a Penning gauge, etc. The sixth vacuum pressure sensor 921 may measure the vacuum pressure of the seventh line 920, and then transmit a signal to the second controller 800 based on the vacuum pressure value. According to some embodiments, the sixth vacuum pressure sensor 921 may be configured to transmit the vacuum pressure of the seventh line 920 to the second controller 800 in real time, or to transmit an abnormal signal to the second controller 800 when the vacuum pressure of the seventh line 920 is greater than or less than a threshold value.

The sixth valve 922 may be configured to adjust a flow rate of the fluid moving through the seventh line 920. According to some embodiments, the sixth valve 922 may include a stop valve, a gate valve, a check valve, a plug valve, a ball valve, a butterfly valve, and a diaphragm valve. In some embodiments, the sixth valve 922 may adjust only the opening and closing of the seventh line 920. In some embodiments, the sixth valve 922 may adjust the opening and closing of the seventh line 920 and the entire flow rate of the fluid. The sixth valve 922 may include an automatic valve. According to some embodiments, the sixth valve 922 may include an electric motor automatic valve, a pneumatic automatic valve, a hydraulic automatic valve, and a solenoid automatic valve.

The third analyzer 502 may be configured to analyze by-products introduced through the seventh line 920. The third analyzer 502 may be configured to analyze parameters of the by-products. For example, the third analyzer 502 may be configured to measure the mass of the by-products. The third analyzer 502 may include a different type of analyzer from each of the first analyzer 500 and the second analyzer 501. In some embodiments, the third analyzer 502 may include an inexpensive analyzer compared to the first analyzer 500.

The second controller 800 may receive parameter analysis values of the by-products from each of the first analyzer 500, the second analyzer 501, and the third analyzer 502. The second controller 800 may compare the parameter analysis values of the by-products received from each of the first analyzer 500, the second analyzer 501, and the third analyzer 502. Accordingly, the substrate processing system 12 may accurately analyze the parameter values of the by-products.

In addition, the second controller 800 may adjust the fifth valve 912 based on the pressure value of the sixth line 910 received from the fifth vacuum pressure sensor 911. For example, when the pressure value of the sixth line 910 is greater than or equal to, or less than or equal to the threshold value, the second controller 800 may close the fifth valve 912 to control the fluid from passing through the sixth line 910. The second controller 800 may adjust the sixth valve 922 based on the pressure value of the seventh line 920 received from the sixth vacuum pressure sensor 921. For example, when the pressure value of the seventh line 920 is greater than or equal to, or less than or equal to a threshold value, the second controller 800 may close the sixth valve 922 to control the fluid not to pass through the seventh line 920. In this manner, the substrate processing system 13 may protect the first analyzer 500, the second analyzer 501, the third analyzer 502, and the processing chamber 100.

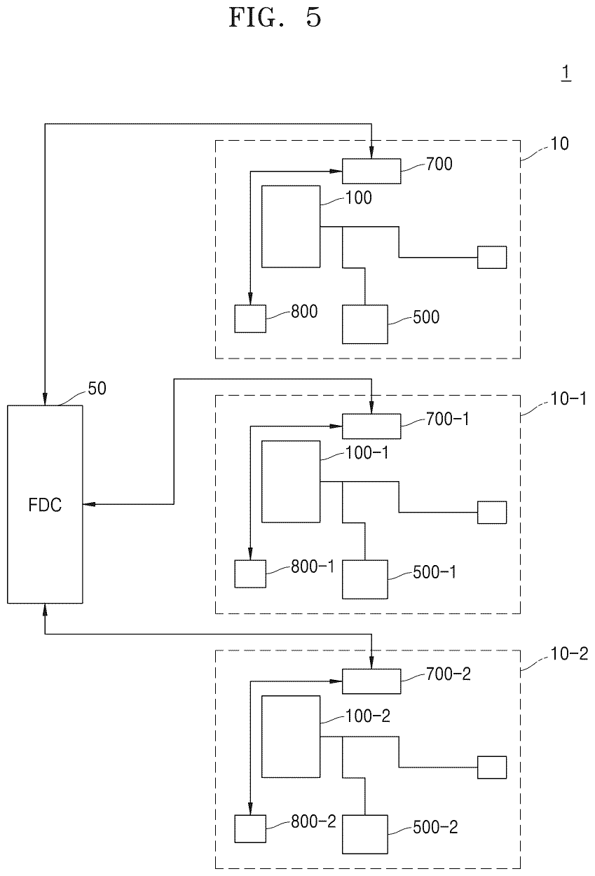

FIG. 5 is a block diagram of a substrate processing center system 1 according to one or more embodiments. Hereinafter, duplicate descriptions of the first substrate processing system 10 given with reference to FIGS. 1 through 2B are omitted and differences are mainly described.

Referring to FIG. 5, the substrate processing center system 1 may include a plurality of substrate processing systems 10, 10-1 and 10-2, and a central controller 50. Each of the plurality of substrate processing systems 10, 10-1 and 10-2 may include a substrate processing system in which the same type of process is performed. Each of a plurality of substrate processing systems 10, 10-1 and 10-2 may include processing chambers 100, 100-1, and 100-2, analyzers 500, 500-1, and 500-2, first controllers 700, 700-1, and 700-2, and second controllers 800, 800-1, and 800-2. The analyzers 500, 500-1, and 500-2 may be configured to analyze the by-products generated by the processing chambers 100, 100-1, and 100-2. The analyzers 500, 500-1, and 500-2 may provide analysis information about the by-products to the second controllers 800, 800-1, and 800-2. The second controllers 800, 800-1, and 800-2 may transmit information about the by-products provided by the analyzers 500, 500-1, and 500-2 to the first controllers 700, 700-1, and 700-2. The first controllers 700, 700-1, and 700-2 may transmit result values of processes performed in the processing chambers 100, 100-1, and 100-2 to the central controller 50.

According to some embodiments, the central controller 50 may include a false detection and classification (FDC) system. The central controller 50 may receive various pieces of information from the first controllers 700, 700-1, and 700-2. According to some embodiments, the central controller 50 may receive result values of processes performed in the processing chambers 100, 100-1, and 100-2 from the first controllers 700, 700-1, and 700-2. For example, the central controller 50 may receive, from the first controllers 700, 700-1, and 700-2, the deposition thickness of a substrate according to a substrate deposition process performed in the processing chambers 100, 100-1, and 100-2. The central controller 50 may transmit a command signal to the first controllers 700, 700-1, and 700-2. The central controller 50 may control the environment inside the processing chambers 100, 100-1, and 100-2 by comparing the process result values of each of the substrate processing systems 10, 10-1 and 10-2 via the first controllers 700, 700-1, and 700-2. For example, when each of the plurality of substrate processing systems 10, 10-1 and 10-2 has a different process result value despite the same environment in the processing chambers 100, 100-1, and 100-2, the central controller 50 may control each of the plurality of substrate processing systems 10, 10-1 and 10-2 to have the same process result value by reconstructing the environment of each of the processing chambers 100, 100-1, and 100-2. For example, when the process result value of any one of the plurality of substrate processing systems 10, 10-1 and 10-2 is low, the central controller 50 may adjust temperature, a mass flow, pressure, or the like in the processing chamber 100 of the first substrate processing system 10 having a low process result value.

Furthermore, because the central controller 50 may receive analysis information about the by-products such as the mass of the by-products from the first controllers 700, 700-1, and 700-2, each of the plurality of substrate processing systems 10, 10-1 and 10-2 may be controlled based on the analysis information about the by-products. For example, when the process result value of any one of the plurality of substrate processing systems 10, 10-1, 10-2 is low, the central controller 50 may control the process result value of the first substrate processing system 10 to come out the same as the process result values of the second and third substrate processing systems 10-1 and 10-2 of the same kind, by adjusting the mass of the by-products of the first substrate processing system 10 having a low process result value. In this manner, the substrate processing center system 1 may control the process result values of the plurality of substrate processing systems 10, 10-1 and 10-2 to be derived.

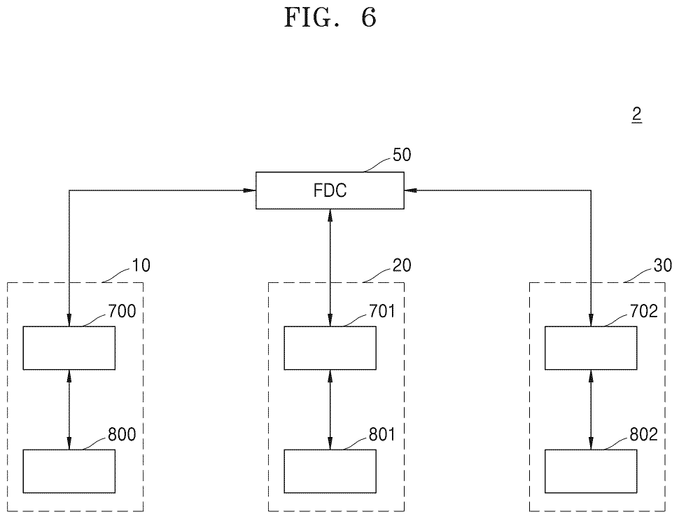

FIG. 6 is a block diagram of a substrate processing center system 2 according to one or more embodiments. Hereinafter, duplicate descriptions of the substrate processing center system 1 given with reference to FIG. 5 and the substrate processing center system 2 to be given with reference to FIG. 6 are omitted, and differences therebetween are mainly described.

Referring to FIG. 6, the substrate processing center system 2 may include the first substrate processing system 10, a second substrate processing system 20, and a third substrate processing system 30. According to some embodiments, each of the first substrate processing system 10, the second substrate processing system 20, and the third substrate processing system 30 may include a substrate processing system in which a process of different type is performed. For example, the substrate deposition process may be performed in the first substrate processing system 10, the substrate etching process may be performed in the second substrate processing system 20, and the substrate cleaning process may be performed in the third substrate processing system 30.

The first substrate processing system 10, the second substrate processing system 20, and the third substrate processing system 30 may include first controllers 700, 701, and 702, and second controllers 800, 801, and 802, respectively. The first controllers 700, 701, and 702 may transmit process result values to the central controller 50. The second controllers 800, 801, and 802 may be configured to transmit the parameters of the by-products measured by an analyzer to the first controllers 700, 701, and 702, respectively.

The central controller 50 may compare the process result values received from the first controllers 700, 701, and 702 and provide a new input value to the first controllers 700, 701, and 702. The first controllers 700, 701, and 702 may control the process internal composition environment by using the input value received from the central controller 50.

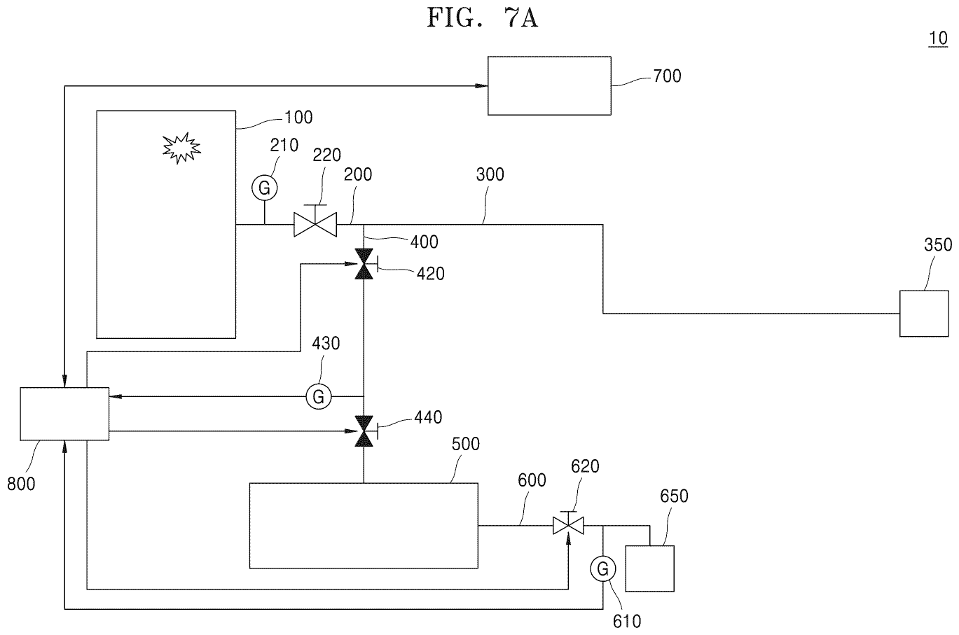

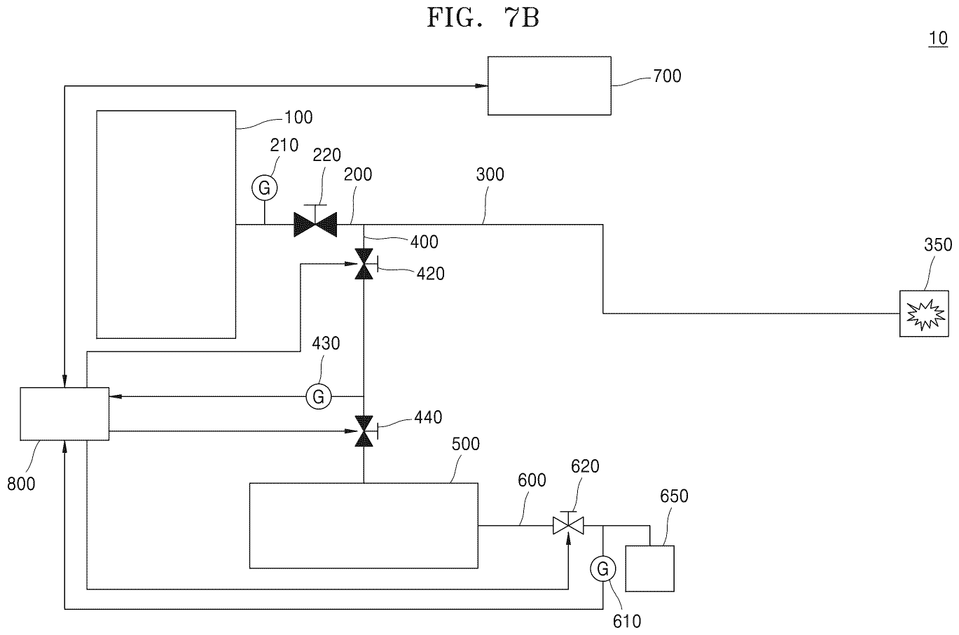

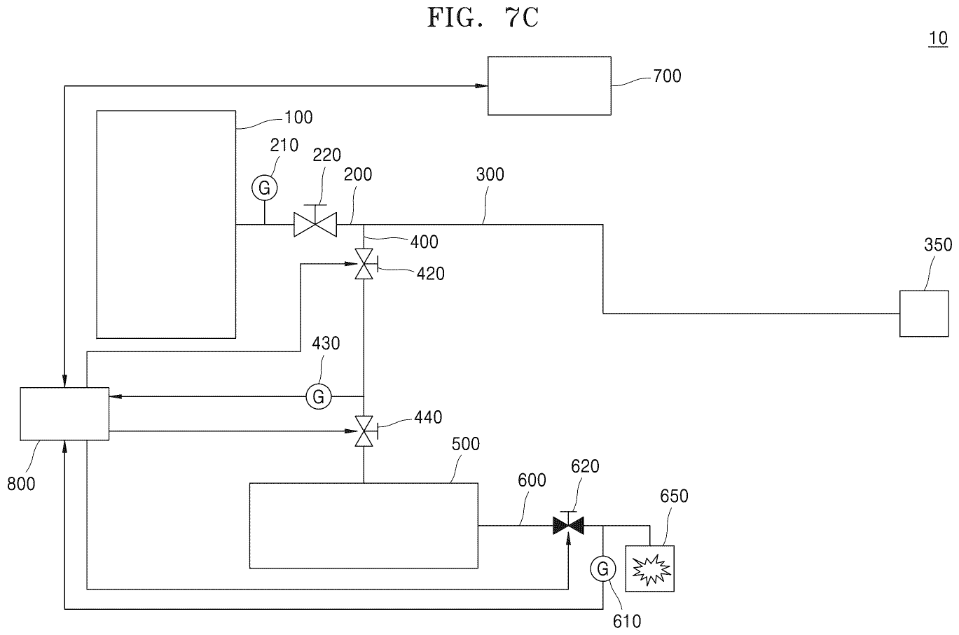

FIGS. 7A through 7C are schematic diagrams of an operation of the substrate processing system 10 of FIG. 1. Hereinafter, duplicate descriptions given with reference to FIGS. 1 through 2B are omitted.

Referring to FIG. 7A, an issue may occur in the processing chamber 100 of the first substrate processing system 10 as a process proceeds. For example, a rapid pressure increase may occur inside the processing chamber 100. In this case, the pressure in the first line 200 and the third line 400 may rapidly increase. In this case, the second controller 800 may receive abnormal signals of the first line 200 and the third line 400 from the first vacuum pressure sensor 210 and the second vacuum pressure sensor 430, respectively, and the second controller 800 may close the second valve 420 and the third valve 440 based on the abnormal signals accordingly. As the second valve 420 and the third valve 440 are converted into a closed state, the high-pressure fluid may not pass through the third line 400, and in this manner, may prevent the high-pressure fluid from flowing into the analyzer 500, and may ultimately protect the analyzer 500 from the high-pressure fluid.

Referring to FIG. 7B, when an issue occurs in the first pump 350 of the first substrate processing system 10, a fluid having moved through the first line 200 and the second line 300 may flow backward. As the fluid flows backward through the first line 200 and the second line 300, a change in the pressure of the first line 200 may occur. In this case, the second controller 800 may receive an abnormal signal from the first vacuum pressure sensor 210, and the second controller 800 may close the first valve 220, the second valve 420, and the third valve 440 in response to the abnormal signal. As the first valve 220 is converted into a closed state, the flowing-backward fluid may be prevented from moving into the processing chamber 100 again. In addition, as the second valve 420 and the third valve 440 are converted into a closed state, the flowing-backward fluid may be prevented from flowing into the analyzer 500.

Referring to FIG. 7C, when an issue occurs in the second pump 650 of the first substrate processing system 10, a fluid that has been discharged by the analyzer 500 and has moved through the fourth line 600 may flow backward. As the fluid flows backward through the fourth line 600, the pressure of the fourth line 600 may be changed. In this case, the second controller 800 may receive an abnormal signal from the third vacuum pressure sensor 610, and the second controller 800 may close the fourth valve 620 in response to the abnormal signal. As the fourth valve 620 is converted into a closed state, the flowing-backward fluid may be prevented from moving into the analyzer 500, and in this manner, the analyzer 500 may be protected.

While the inventive concept has been particularly shown and described with reference to embodiments thereof, it will be understood that various change in form and details may be made therein without departing from the spirit and scope of the following claims.

1. A substrate processing system comprising:
a processing chamber in which process by-products are to be generated;
a first line configured to provide a path through which the process by-products are discharged to outside the processing chamber;
a first vacuum pressure sensor located on the first line and configured to measure a vacuum pressure value of the first line;
a first valve located on the first line and configured to adjust a flow rate of a fluid passing through the first line;
a second line connecting the first line to a first pump;
a first analyzer configured to analyze parameters of the process by-products;
a third line connecting the first line to the first analyzer;
a second vacuum pressure sensor located on the third line and configured to measure a vacuum pressure value of the third line;
a second valve located on the third line and configured to adjust a flow rate of a fluid passing through the third line; and
a first controller configured to control the first valve based on a signal received from the first vacuum pressure sensor and control the second valve based on a signal received from the second vacuum pressure sensor.

2. The substrate processing system of claim 1, further comprising:
a plurality of processors in the processing chamber, wherein the plurality of processors comprise a space in which a substrate is processed.

3. The substrate processing system of claim 1, further comprising:
a third valve provided on the third line and configured to adjust the flow rate of the fluid passing through the third line,
wherein the first controller is configured to control the third valve based on a signal received from the second vacuum pressure sensor.

4. The substrate processing system of claim 3, further comprising:
a fourth vacuum pressure sensor provided on the third line and configured to measure the vacuum pressure value of the third line, wherein the fourth vacuum pressure sensor is located between the second valve and the first line.

5. The substrate processing system of claim 1, further comprising:
a fourth line connecting the first analyzer to a second pump;
a third vacuum pressure sensor provided on the fourth line and configured to measure a vacuum pressure value of the fourth line; and
a fourth valve provided on the fourth line and configured to adjust a flow rate of a fluid passing through the fourth line,
wherein the first controller is further configured to control the fourth valve based on a signal received from the third vacuum pressure sensor.

6. The substrate processing system of claim 1, further comprising:
a fifth line connected to the third line;
a second analyzer configured to analyze parameters of the process by-products discharged by the processing chamber, the second analyzer being connected to the fifth line;
a fifth vacuum pressure sensor provided on the fifth line and configured to measure a vacuum pressure value of the fifth line; and
a fifth valve provided on the fifth line and configured to adjust a flow rate of a fluid passing through the fifth line.

7. The substrate processing system of claim 6, wherein the first controller is further configured to control the fifth valve based on a signal received from the fifth vacuum pressure sensor.

8. The substrate processing system of claim 1,
wherein the first controller is further configured to transmits a result value of a process performed in the processing chamber to a central controller, and
wherein the central controller is configured to generate an environment in the processing chamber based on the result value of the process.

9. The substrate processing system of claim 8, wherein the central controller is further configured to generate the environment in the processing chamber based on a mass of the process by-products received from the first controller.

10. The substrate processing system of claim 1, wherein the first analyzer comprises a time of flight (TOF)—mass spectrometry (MS) (TOF-MS) analyzer.

11. A substrate processing system comprising:
a processing chamber in which process by-products are to be generated;
a first line configured to provide a path through which the process by-products are discharged to outside the processing chamber;
a first vacuum pressure sensor located on the first line and configured to measure a vacuum pressure value of the first line;
a first valve located on the first line and configured to adjust a flow rate of a fluid passing through the first line;
a second line connecting the first line to a first pump;
an analyzer configured to analyze parameters of the process by-products;
a third line connecting the first line to the analyzer;
a second vacuum pressure sensor located on the third line and configured to measure a vacuum pressure value of the third line;
a second valve located on the third line and configured to adjust a flow rate of a fluid passing through the third line;
a first controller configured to control the first valve based on a signal received from the first vacuum pressure sensor; and
a second controller configured to:
receive parameter analysis values from the analyzer of the process by-products;
control the second valve based on a signal received from the second vacuum pressure sensor; and
transmit the parameter analysis values to the first controller.

12. The substrate processing system of claim 11, further comprising:
a fourth vacuum pressure sensor provided on the third line and configured to measure the vacuum pressure value of the third line and a third valve configured to adjust the flow rate of the fluid passing through the third line, wherein the second controller is further configured to control the second valve and the third valve based on signals received from the second vacuum pressure sensor and a third vacuum pressure sensor.

13. The substrate processing system of claim 11, further comprising:
a fourth line connecting the analyzer to a second pump;
a third vacuum pressure sensor on the fourth line and configured to measure a vacuum pressure value of the fourth line; and
a fourth valve on the fourth line and configured to adjust a flow rate of a fluid passing through the fourth line,
wherein the second controller is further configured to control the fourth valve in response a signal received from the third vacuum pressure sensor.

14. The substrate processing system of claim 11, further comprising:
a fifth line connected to the third line;
a sixth line and a seventh line connected to the fifth line;
a second analyzer configured to analyze parameters of the process by-products discharged by the processing chamber, the second analyzer being connected to the sixth line;
a third analyzer configured to analyze parameters of the process by-products discharged by the processing chamber, the third analyzer being connected to the seventh line;
a fifth vacuum pressure sensor provided on the sixth line and configured to measure a vacuum pressure value of the sixth line;
a fifth valve provided on the sixth line and configured to adjust a flow rate of a fluid passing through the sixth line;
a sixth vacuum pressure sensor provided on the seventh line and configured to measure a vacuum pressure value of the seventh line; and
a sixth valve provided on the seventh line and configured to adjust a flow rate of a fluid passing through the seventh line.

15. The substrate processing system of claim 14,
wherein the second controller is further configured to control the fifth valve based on a signal received from the fifth vacuum pressure sensor, and control the sixth valve based on a signal received from the sixth vacuum pressure sensor.

16. The substrate processing system of claim 11,
wherein the first controller is further configured to transmit the parameter analysis values of the process by-products and a result value of a process performed in the processing chamber to a central controller, and
wherein the central controller is configured to generate an environment in the processing chamber based on the result value of the process.

17. The substrate processing system of claim 16, wherein the central controller is further configured to generate the environment in the processing chamber based on a mass of the process by-products received from the first controller.

18. A substrate processing system comprising:
a processing chamber in which process by-products are to be generated;
a first line configured to provide a path through which the process by-products are discharged to outside the processing chamber;
a first vacuum pressure sensor located on the first line and configured to measure a vacuum pressure value of the first line;
a first valve located on the first line and configured to adjust a flow rate of a fluid passing through the first line;
a second line connecting the first line to a first pump;
an analyzer configured to analyze parameters of the process by-products;
a third line connecting the first line to the analyzer;
a second vacuum pressure sensor located on the third line and configured to measure a vacuum pressure value of the third line;
a second valve located on the third line and configured to adjust a flow rate of a fluid passing through the third line, the second valve being arranged near the first line;
a third valve located on the third line, and configured to adjust the flow rate of the fluid passing through the third line, the third valve being arranged near the analyzer;
a fourth line connecting the analyzer to a second pump;
a third vacuum pressure sensor located on the fourth line and configured to adjust a flow rate of a fluid passing through the fourth line;
a fourth valve located on the fourth line and configured to adjust the flow rate of the fluid passing through the fourth line;
a first controller configured to control the first valve based on a signal received from the first vacuum pressure sensor; and
a second controller configured to:
receive parameter analysis values from the analyzer of the process by-products;
control the second valve and the third valve based on the signal received from the second vacuum pressure sensor;
control the fourth valve based on the signal received from the third vacuum pressure sensor; and
transmit the parameter analysis values to the first controller.

19. The substrate processing system of claim 18, wherein the analyzer comprises a time of flight (TOF)—mass spectrometry (MS) (TOF-MS) analyzer.

20. The substrate processing system of claim 18, comprising:
a fifth line connected to the third line;
a second analyzer configured to analyze parameters of the process by-products discharged by the processing chamber, the second analyzer being connected to the fifth line;
a fifth vacuum pressure sensor provided on the fifth line and configured to measure a vacuum pressure value of the fifth line; and
a fifth valve provided on the fifth line and configured to adjust a flow rate of a fluid passing through the fifth line,
wherein the second controller is further configured to control the fifth valve based on a signal received from the fifth vacuum pressure sensor.

21. (canceled)
